(19) United States
(12) Patent Application Publication
(10) Pub. No.: US 2007/0230115 A1
(43) Pub. Date: Oct. 4, 2007

(54) Memory module

(76) Inventors: Stephan Dobritz, Dresden (DE); Diether Sommer, Planegg (DE); Harald Grune, Dresden (DE)

Correspondence Address: SLATER & MATSIL LLP, 17950 PRESTON ROAD, SUITE 1000, DALLAS, TX, 75252, US

(21) Appl. No.: 11/707,741

(22) Filed: Feb. 16, 2007

Related U.S. Application Data
(63) Continuation-in-part of application No. 11/390,981, filed on Mar. 27, 2006, now abandoned.

(30) Foreign Application Priority Data
Feb. 16, 2006 (DE) 10 2006 007 303.7

(51) Int. Cl. H05K 7/20; H05K 7/02

(52) U.S. Cl. 361/688; 361/760

(57) ABSTRACT

A memory module includes a printed circuit board having a lateral contact portion and a plurality of memory chips being electrically coupled to the printed circuit board and arranged side-by-side at least one printed circuit board assembly side. An encapsulating-covering element is formed on the printed circuit board at the at least one printed circuit board assembly side. Furthermore, the plurality of memory chips are embedded in the encapsulating-covering element.

This application is a continuation-in-part of U.S. patent application Ser. No. 11/390,981, entitled “Printed Circuit Board Configuration,” filed on Mar. 27, 2006, which application claims priority to German Patent Application Serial No. 10 2006 007 303.7, filed on Feb. 16, 2006, both of which applications are incorporated herein by reference.

### TECHNICAL FIELD

The present invention relates to a memory module.

### BACKGROUND

A conventional memory module usually serves as an extension component for an electronic device such as, e.g., a personal computer, a printer, a server, etc., and is usually configured to be plugged into, e.g., a plug-in port, also referred to as a slot, provided at a printed circuit board. Such a memory module usually includes a printed circuit board having a contact strip at its side and a plurality of memory chips, which are electrically connected to the printed circuit board.

### SUMMARY OF THE INVENTION

In an embodiment of the invention, a memory module is provided. The memory module includes a printed circuit board having a lateral contact portion and a plurality of memory chips being electrically coupled to the printed circuit board and being arranged side-by-side at least one printed circuit board assembly side. An encapsulating-covering element is formed on the printed circuit board at the at least one printed circuit board assembly side. Furthermore, the plurality of memory chips are embedded in the encapsulating-covering element.

### BRIEF DESCRIPTION OF THE DRAWINGS

For a more complete understanding of the present invention, and the advantages thereof, reference is now made to the following descriptions taken in conjunction with the accompanying drawings, in which:

FIG. 1a is a cross-sectional view of an exemplary embodiment of a printed circuit board configuration;

FIG. 1b is a plan view of the printed circuit board configuration shown in FIG. 1a;

FIG. 1c is a plan view of an exemplary embodiment of a configuration of cooling ribs;

FIG. 1d is a plan view of an exemplary embodiment of a configuration of cooling ribs;

FIG. 2 is a cross-sectional view of an exemplary embodiment of a printed circuit board configuration;

FIG. 3 is a cross-sectional view of an exemplary embodiment of a printed circuit board configuration;

FIG. 4 is a cross-sectional view of an exemplary embodiment of a printed circuit board configuration;

FIG. 5 is a cross-sectional view of an exemplary embodiment of a printed circuit board configuration; and

FIG. 6 is a cross-sectional view of an exemplary embodiment of a printed circuit board configuration.

### DETAILED DESCRIPTION OF ILLUSTRATIVE EMBODIMENTS

In the drawing figures, the same components are provided with identical reference numerals.

There usually exist various requirements for a memory module. Depending on the specific requirements for a memory module, in an embodiment of the invention, the usually provided printed circuit board of the memory module may be provided on one side or on two opposite sides with memory chips and possibly with additional electronic components with high packing density. The memory chips and the additional electronic components may be electrically connected to the printed circuit board by means of solder bumps or by means of other suitable electrical connecting elements.

Furthermore, conventionally, during the operation of an electronic device, such as a PC (Personal Computer) for example, heat is generated by the electronic components inside the device. Sometimes the generated heat is at a very high temperature that can adversely influence the functional capability of the memory chips and additional electronic components, possibly even causing these memory chips and components to become inoperative or be destroyed. In particular, integrated circuits (ICs) are generally affected. Such integrated circuits, e.g., the memory chips depending on the embodiment, are packaged or unpackaged memory chips that are electrically connected to the printed circuit boards (PCBs).

For this reason, it is desirable to provide means for dissipating the heat generated from the electronic components.

Conventional solutions for dissipating heat from memory chips arranged on a printed circuit board have various disadvantages. One such disadvantage, for example, is requiring many different and separate individual components for each memory module, which has a high cost. Another disadvantage is requiring heat conducting paste or elastomers to improve the heat transmission and to compensate for mechanical tolerances.

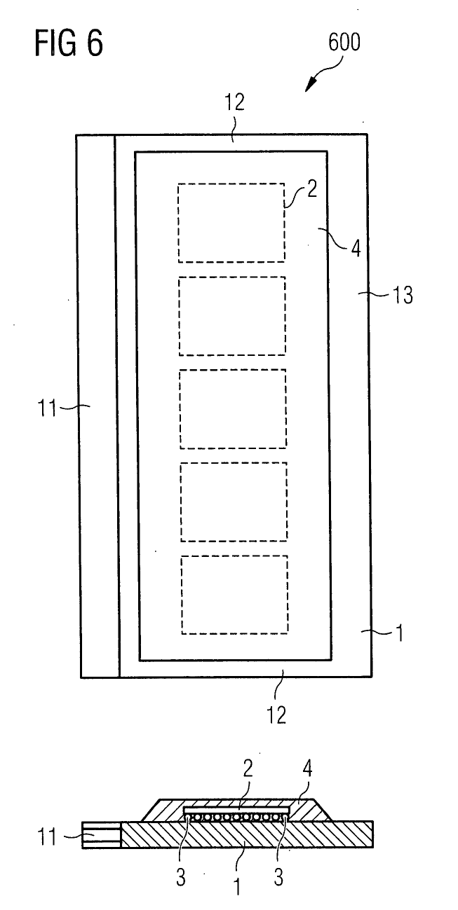

FIG. 6 is a cross-sectional view of an exemplary embodiment of a printed circuit board configuration, e.g., a memory module 600, in two views. The memory module 600 shown includes a printed circuit board 1, which includes a contact portion 11 at one longitudinal edge of its longitudinal edges. The contact portion 11 of the memory module 600 may be inserted into a plug-in location, e.g., a slot, which is provided in a mainboard of an electronic device, to provide an electrical connection with it. A plurality of memory chips are arranged next to one another in one or more rows on the printed circuit board 1. Furthermore, additional electronic components (not shown), which may be provided for operating the memory module 600, for example, may be arranged on the printed circuit board 1. An encapsulating-covering element 4 is formed on the printed circuit board assembly side, on which the memory chips 2 are also arranged. In an embodiment of the invention, some or all of the electronic components are incorporated (e.g., molded) into the encapsulating-covering element 4.

FIG. 6 further illustrates that the encapsulating-covering element 4, which may be formed in a plate shape, may be surrounded by a rear edge portion 13 being located opposite to the contact portion 11, and two lateral edge portions 12 of the printed circuit board 1. The casting mold (which may be used for inject molding of the encapsulating-covering element 4, for example) is densely supported by the rear edge portion 13 and the two lateral edge portions 12 and by a portion in the region of the contact portion 11.

As illustrated in the cross-sectional view of FIG. 6 the memory chips 2 are electrically conductively coupled to the printed circuit board 1 by means of solder bumps 3. The memory chips 2 may be packaged chips or unpackaged chips. In an embodiment of the invention, the memory chips 2 may be packaged as wafer level package (WLP) chips or unpackaged wafer level package (WLP) chips. In an embodiment of the invention, only one assembly side of the printed circuit board 1 of the memory module 600 is provided with memory chips 2 and the corresponding encapsulating-covering element 4. In an alternative embodiment of the invention, both assembly sides of the printed circuit board 1 of the memory module 600 are provided with memory chips 2 and the corresponding encapsulating-covering element 4.

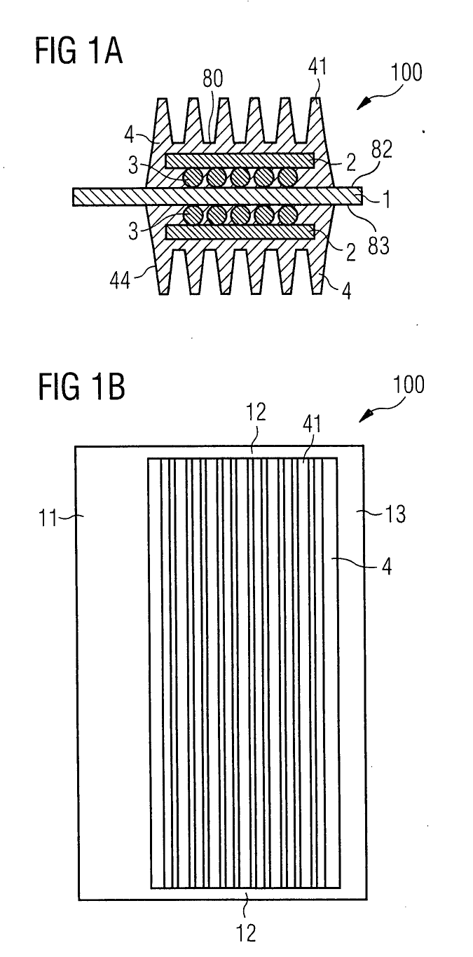

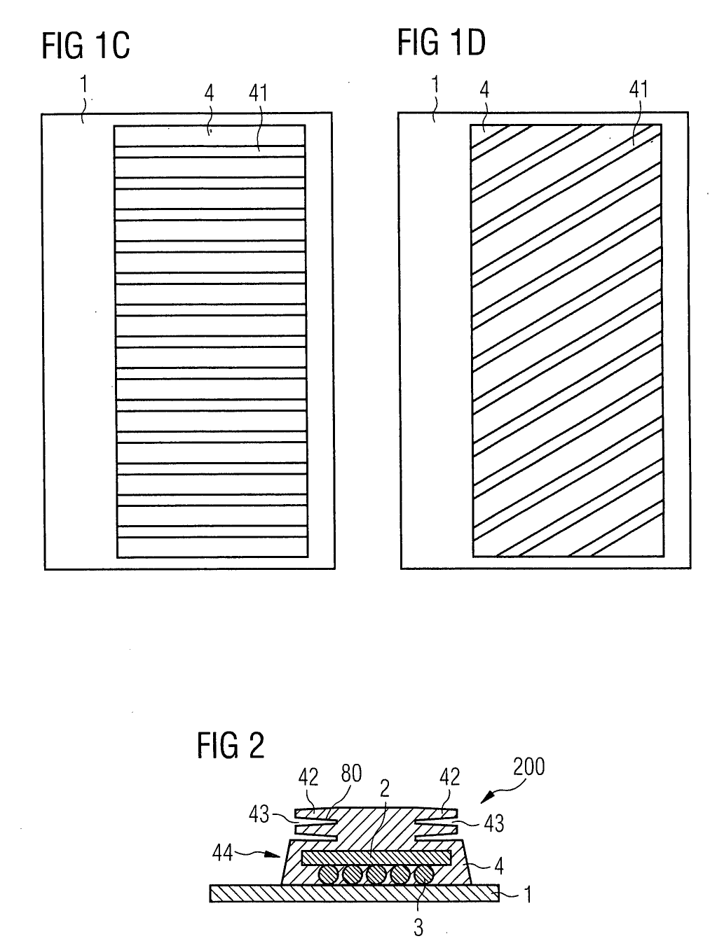

FIG. 1a is a cross-sectional view of an exemplary embodiment of a printed circuit board configuration 100, e.g. a memory module (e.g., further including heat dissipating elements), including a printed circuit board 1. The cross-sectional view is taken transversely to the longitudinal extent of the printed circuit board 1.

Although FIG. 1a and FIGS. 2-5 schematically show only one chip 2 (e.g. memory chip) in each case, in practice, a plurality of chips 2 are respectively arranged at a distance from one another in the longitudinal direction of the printed circuit board 1 of the memory module. Furthermore, even though this is not shown, depending on the function of the corresponding printed circuit board 1, two or more such rows of memory chips 2, extending in the longitudinal direction of the printed circuit board 1, may be configured on the printed circuit board 1. Therefore, hereinafter, reference will be made to a plurality of memory chips 2.

As can be seen from FIG. 1a, both sides of the printed circuit board 1 of the memory module are loaded with a plurality of memory chips 2. A plurality of solder bumps 3 or other suitable connecting elements (not represented) electrically conductively connect the plurality of chips 2 to the printed circuit board 1. The chips 2 are completely embedded in a respective encapsulating-covering element 4, which forms a composite structure with the printed circuit board 1. The intermediate spaces between the solder bumps 3 are also filled with encapsulating compound. The encapsulating-covering element 4 has a heat dissipating element constructed as a multiplicity of cooling ribs 41 formed on the side of the encapsulating-covering element 4 facing away from the printed circuit board 1. The multiplicity of cooling ribs 41 are produced in one piece with the encapsulating-covering element 4 during the molding process. In the case of a customary memory module having a printed circuit board with dimensions of about 30 mm×150 mm, for example, more than 10 cooling ribs 41 are formed next to one another. The encapsulating-covering element, for example, has a total height of 5 mm. The cooling ribs 41 are approximately 4 mm high. As can be seen from FIG. 1a, all four peripheral edges of the encapsulating-covering element 4 are formed in such a way that they are inclined obliquely inward from the printed circuit board 1. The illustrated cross-section shows the cooling ribs 41 formed in the shape of an isosceles trapezium. On account of this configuration, which corresponds to the complementary formed casting mold (cavity), after the casting compound is cured, the casting mold can be removed upward from the printed circuit board 1, or the printed circuit board 1 can be ejected downward easily without having to destroy the mold.

FIG. 1b is a plan view of the memory module 100 shown in FIG. 1a. As can be seen from FIG. 1b, the printed circuit board 1 of the memory module 100 is covered almost completely by the encapsulating-covering element 4. Only narrow edge portions 12, which are formed for inserting the printed circuit board 1 into a clearance (not shown), a front edge portion 11, on which the printed circuit board contacts (not represented) are formed, and a narrow rear edge portion 13 are not covered by the encapsulating-covering element 4. The casting mold is supported in close engagement on these edge portions 11, 12, and 13 during molding. The integrally attached cooling ribs 41 extend substantially parallel to one another in the longitudinal direction of the printed circuit board 1. The predetermined distance between the cooling ribs 41 ensures that an optimum heat exchange can take place between the individual cooling ribs 41 and the ambient air. To assist the heat exchange with the ambient air, a fan (not shown), from which the cooling air is fed, for example, in the direction of the cooling ribs 41, may be arranged in the end device (not shown).

As represented in FIGS. 1c and 1d, the cooling ribs 41 of the encapsulating-covering element 4 may also be aligned transversely to the longitudinal direction of the memory module (FIG. 1c) or obliquely to the longitudinal direction of the memory module 100 (FIG. 1d). This alignment of the cooling ribs 41 may be predetermined, dependent, for example, on a customer request or the configuration of the end device. The alignment of the cooling ribs 41 is realized by a corresponding casting mold that is formed in a way to complement the encapsulating-covering element 4.

FIG. 2 is a cross-sectional view of an exemplary embodiment of a printed circuit board configuration 200, e.g., a memory module 200, including a printed circuit board 1 having a plurality of memory chips 2 soldered on (only one such chip 2 can be seen in the cross-sectional view). The heat dissipating element is constructed as a plurality of cooling ribs 42 that are integrally attached to the encapsulating-covering element 4. The cooling ribs 42 extend substantially parallel to the plane of the printed circuit board 1. The cooling ribs 42 are in this case formed by depressions 43 that extend from the two mutually opposite longitudinal side edges into the interior of the encapsulating-covering element 4. Given a printed circuit board with dimensions of 30 mm×150 mm, the depth of the depressions 43, and consequently the length of the cooling ribs, is ideally about 10 mm. The depressions 43 are made by using projections that project from the corresponding wall of the casting mold. The upper side 80 of the encapsulating-covering element is formed such that it is inclined toward its longitudinal sides and each of the cooling ribs 42 has a cross-section tapering from the inside outward, so that after the casting compound has cured, each part of the approximately centrally divided two-part casting mold can be easily removed from the printed circuit board 1 in a direction approximately parallel to the plane of the printed circuit board. Although two cooling ribs 42, which are formed by two depressions 43, are respectively represented in FIG. 2 on both sides of the encapsulating-covering element 4, it is also possible for only one or more than two cooling ribs 42 to be formed on each side.

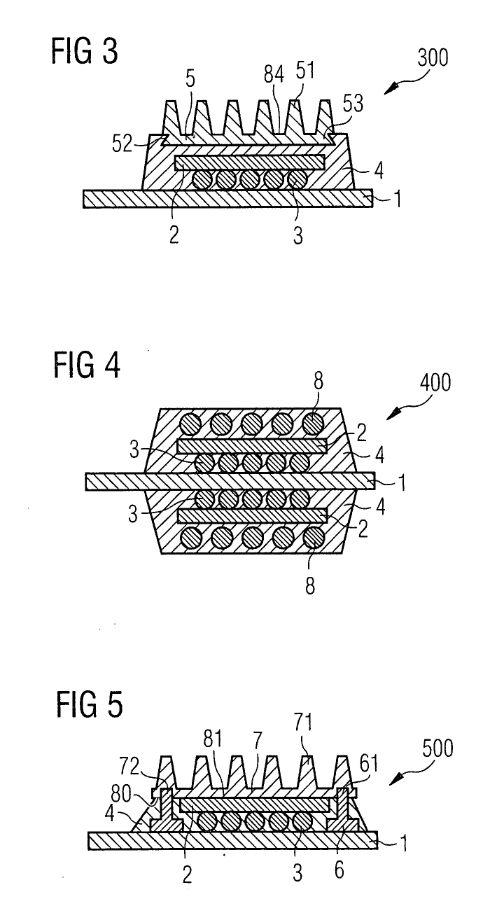

FIG. 3 is a cross-sectional view of an exemplary embodiment of a printed circuit board configuration 300, e.g., a memory module 300, including a printed circuit board 1 in which the heat dissipating element is a separate heat sink 5 incorporated on the upper side of the encapsulating-covering element 4 during molding. The heat sink 5 has a substantially planar base plate 53. The planar base plate 53 has an upper side that faces away from the printed circuit board 1 and that has a plurality of cooling ribs 51 formed thereon. The cooling ribs 51 extend in the longitudinal direction of the printed circuit board 1, as in the case of the embodiment shown in FIGS. 1a and 1b. The form of the upper side of the encapsulating-covering element 4 may be adapted so that the base plate 53 has a basic rectangular form. The width and length of the base plate 53 is somewhat smaller than the surface of the upper side of the encapsulating-covering element 4 that encloses the edges of the base plate 53. Instead of the single heat sink 5 shown, it is also possible for a number of such heat sinks 5 to be configured next to one another in the longitudinal direction of the memory module 300 or the printed circuit board 1. In this case, the base plates of the number of such heat sinks 5 are then made correspondingly smaller. In this embodiment, the intermediate space between the chips 2, which are connected to the printed circuit board 1 by solder bumps 3, and the underside of the heat sink 5 is filled with encapsulating compound (casting compound). That is to say, in this embodiment, the chips 2 are surrounded by casting compound on all sides.

A recess 52 is formed as a continuous longitudinal groove in at least the longitudinal side edges of the heat sink 5. The longitudinal side edges of the heat sink 5 extend in the longitudinal direction of the printed circuit board 1. Casting compound enters the recess 52 during the molding process, so that after the curing of the casting compound, a form fit connection is obtained between the casting compound and the recess 52. Forming the encapsulating-covering element 4 on the printed circuit board 1 and simultaneously incorporating the heat sink 5 in the encapsulating-covering element 4 by means of molding has the effect that a composite structure is formed in a single production step. This composite structure includes the encapsulating-covering element 4, the heat sink 5, and the printed circuit board 1. In this way, the heat sink 5 is securely fixed on the encapsulating-covering element 4. An edge forming the downward delimitation (that is in the direction of the printed circuit board 1) of the recess 52 of the base plate 53 is covered by cured casting compound, making it impossible for the heat sink 5 to be removed from the encapsulating-covering element 4 even if great force is applied. A further advantage of this memory module 300 is also that, on account of this composite structure between the encapsulating-covering element 4 and the heat sink 5, there is a homogeneous transition, so that an optimum heat exchange can take place between these two. Such a recess 52 may also be formed on all four peripheral edges of the base plate 53 of the heat sink 5, so that the lower edge of the base plate 53, forming the lower delimitation of the recess 52, is incorporated in the encapsulating-covering element 4 on all four sides, and consequently the heat sink 5 is incorporated on all sides.

FIG. 4 is a cross-sectional view of an exemplary embodiment of a printed circuit board configuration 400, e.g., a memory module 400, including a printed circuit board 1 loaded with memory chips 2 on two sides (e.g., on both printed circuit board assembly sides). In this configuration, solder bumps 3 connect the chips 2 in an electrically conducting manner to the printed circuit board 1. Accordingly, the printed circuit board 1 also has the encapsulating-covering element 4 on both its sides. A heat dissipating element constructed as a cooling coil 8, carrying a cooling medium, is respectively incorporated in each of the encapsulating-covering elements 4. The cooling coil 8 is formed by a tube that winds sinuously back and forth in the plane parallel to the plane of the printed circuit board 1. The straight portions may extend in the longitudinal direction of the printed circuit board 1 and the curved portions are formed in the regions of the two longitudinal ends of the encapsulating-covering element 4. The connection portions (not shown) of the cooling coil 8 that are necessary for the circulation of the cooling medium extend from the encapsulating-covering element 4, so that they can be connected to corresponding connecting portions of a heat exchanger. In one embodiment of the invention, the cooling coil 8 is arranged in each case only at a small distance from the sides of the chips 2 that are facing away from the printed circuit board 1, so that good heat dissipation of the heat generated by the chips 2 is provided. In the case of this embodiment, the encapsulating-covering element 1 has the shape of a truncated pyramid with a rectangular base area. The connection portions of the cooling coil 8 may be supported on the casting mold such that the cooling coil 8 is held in the position in which it is to be incorporated in the encapsulating-covering element 4. To produce this encapsulating-covering element 4, the casting mold should consequently be formed in two parts.

FIG. 5 is a cross-sectional view of an exemplary embodiment of a printed circuit board configuration 500, e.g., a memory module, including a printed circuit board 1, a plurality of memory chips 2 electrically connected to the printed circuit board 1, and an encapsulating-covering element 4 embedding the chips 2. The inactive side, which is facing away from the printed circuit board 1, of each of the chips 2 is exposed and arranged in the same plane as the upper side of the encapsulating-covering element 4.

The encapsulating-covering element 4 represented in FIG. 5 has two fastening elements 6 that are incorporated during molding. In this exemplary embodiment, the fastening elements 6 may be formed by T-section rail portions. The web of the T-section is supported on the printed circuit board 1. The free end portion 61 of the T-leg protrudes above the upper side of the encapsulating-covering element 4. A respective fastening element 6 is arranged in a region of a longitudinal side edge of the encapsulating-covering element 4 and may extend in the longitudinal direction of the printed circuit board 1 substantially over the entire length of the encapsulating-covering element 4. The fastening elements 6 may, however, also be shorter portions of a T section, a head bolt or the like, of which at least on each side of one instead of both T-section rail portions are arranged.

The end portion 61 of the fastening elements 6 protruding from the encapsulating-covering element 4 serve for fastening at least one heat dissipating element constructed as a heat sink 7. The heat sink 7 has a multiplicity of cooling ribs 71 and may be formed in a way similar to the heat sink 5 disclosed in one of the embodiments described above. The heat sink 7 represented here likewise has recesses 72, which however are formed in the underside of its base plate. The form of the recesses 72 is adapted to the form of the incorporated fastening elements 6. That is to say, if the fastening elements 6 are head bolts for example, and consequently the portions 61 protruding from the encapsulating-covering element are cylindrical, the recesses 72 are holes formed in a corresponding size. If, however, the fastening elements 6 are T-section rail portions and the portions 61 consequently protruding from the encapsulating-covering element 4 have the form of planar rails, the recesses 72 have the form of longitudinal grooves. By using the fastening elements 6, which are incorporated in the encapsulating-covering element 4, it is possible to fasten a heat sink 7 on the encapsulating-covering element 4 in a simple manner, and consequently to fasten the heat sink 7 onto the bare, inactive, exposed back sides of the chips 2. This is accomplished by bringing the free end portion 61 of the fastening elements 6 into engagement (with a form fit) with the complementary formed recesses 72 of the heat sink 7.

Instead of the incorporated fastening elements 6, integrally attached fastening elements (not represented) may also be provided on the encapsulating-covering element 4. Such fastening elements will extend upward from the upper side of the encapsulating-covering element 4. These attached fastening elements may have any possible cross-sectional shape that can be formed by molding. For example, the shape can be frustoconical, trapezoidal, or the like, onto which a heat sink 7 can then be placed or fitted, so that the planar underside of the heat sink 7 is held in close contact with the upper side of the encapsulating-covering element 4 and the inactive back side of the packaged or unpackaged chips 2. Also in the case of the configuration with the integrally attached fastening elements, the encapsulating-covering element could be provided with a layer of casting compound that completely covers the chips 2. Another option is to form the upper side of the encapsulating-covering element in one plane with the upper side, which is facing away from the printed circuit boards, of the chips.

According to an exemplary embodiment of the invention, the printed circuit board, which has the plurality of chips, e.g., memory chips, electrically connected to the printed circuit board, has an encapsulating-covering element that encloses all the chips, e.g., memory chips. Furthermore, there is at least one heat dissipating element that is either integrally attached during the molding of the encapsulating-covering element or that is incorporated during the molding. That is to say that, during the production of the composite structure between the printed circuit board and the encapsulating-covering element, the heat dissipating elements are attached or incorporated at the same time. It is not necessary for individual elements intended for cooling to be arranged subsequently. Improved heat dissipating behaviour is consequently provided by the increased surface of the encapsulating-covering element and also by the heat dissipating element. The encapsulating-covering element may be produced from an epoxy resin or a filled epoxy resin by the injection-molding process. This material allows itself to be poured very well and also is distinguished by optimum thermal conductivity.

In one embodiment of the invention, the heat dissipating element is a cooling rib produced in one piece with the encapsulation-covering element. This cooling rib may be produced in a simple way by using a correspondingly shaped depression in the casting mold (cavity) during the molding from the casting material itself. It goes without saying here that the depression is formed in such a way that, after curing of the casting material, the casting mold can be separated or removed from the printed circuit board without destroying the printed circuit board. The depression in the casting mold, consequently the cooling rib itself, may have a cross-sectional shape in the form of an isosceles trapezium.

In one configuration of this embodiment, the cooling rib projects from the upper side of the encapsulating-covering element. After projecting from the upper side, the cooling rib then extends in the longitudinal direction of the printed circuit board, extends transversely to the longitudinal direction of the printed circuit board, or extends obliquely to the longitudinal direction of the printed circuit board. The alignment of the cooling rib projecting from the upper side of the encapsulating-covering element can be selected depending on the intended use of the printed circuit board and the arrangement of an additional device that boosts the cooling effect, such as for example, a fan located in the corresponding end device.

In one configuration, a multiplicity of cooling ribs are arranged at a distance from one another. In this way, the total area that is formed by the encapsulating-covering element and available for heat dissipation can be determined.

In another configuration of the aforementioned embodiment, the cooling rib is formed by at least one depression formed in at least one of the peripheral edges of the encapsulating-covering element. The depression extends substantially parallel to the plane of the printed circuit board. In the present case, this means that the cooling rib is formed by at least one depression extending from one of the narrow peripheral edges into the interior of the encapsulating-covering element over a specific length and depth, and extending substantially parallel to the plane of the encapsulating-covering element. The cross-sectional shape of the depression may be formed in a triangular manner. The cooling rib is bounded by the upper side of the encapsulating-covering element on the one hand and by the depression on the other hand.

In one embodiment, at least one such cooling rib is respectively formed in two mutually opposite narrow sides of the encapsulating-covering element. These cooling ribs consequently are, e.g., formed on the peripheral edges of the encapsulating-covering element extending in the longitudinal direction of the printed circuit board or extending transversely to the longitudinal direction of the printed circuit board. Two depressions at a vertical distance from each other may be used, for example, for forming two cooling ribs. The depressions in the peripheral edges of the encapsulating-covering element are formed by corresponding projections on the side wall of the casting mold. It goes without saying that, in the case where such cooling ribs are to be attached on two mutually opposite peripheral edges, the casting mold is formed as two parts.

In one embodiment of the invention, the heat dissipating element is a heat sink arranged on the upper side of the encapsulating-covering element, and portions of the heat sink are incorporated in the encapsulating-covering element. This means that the heat dissipating element that is incorporated, at least in certain portions, on the upper side of the encapsulating-covering element can be a heat sink which in fact is initially separate and can be produced from a material of a thermal conductivity that exceeds that of the encapsulating-covering element. The heat sink may, for example, be produced from aluminum, copper or the like. A composite structure is produced between the predetermined portions of the heat sink that are incorporated in the encapsulating-covering element during the molding and the regions of the encapsulating-covering element surrounding these portions. A homogeneous transition is created in the composite region between the encapsulating-covering element and the heat sink for optimum heat transmission or heat dissipation. The portions of the heat sink that protrude from the upper side of the encapsulating-covering element are in sealed connection with the casting mold. Since the connection between the encapsulating-covering element, which covers the printed circuit board substantially completely, and the heat sink is produced by incorporation in a single working step, that is to say the molding, the chip-loaded printed circuit board can be completed in a single completing step. To produce the printed circuit board it is not necessity to use conventional additional fastening means, such as screws, clips, etc. Nor is it necessary to use conventional cost-intensive underfilling materials between the chip and the printed circuit board, for example, heat-conducting paste between the chip package or the bare chip and the heat dissipating element. The accompanying series of working and completing steps for fastening or underfilling are of course also not needed for producing the printed circuit board.

In one configuration of the aforementioned embodiment, the heat sink is formed by a base plate with cooling ribs formed on its upper side. Two of the peripheral edge recesses of the heat sink are filled with casting compound. The entry of casting material into these lateral recesses of the heat sink and the subsequent curing of the casting material have the effect that the heat sink is advantageously fastened on the encapsulating-covering element by means of a form fit. The recesses in the heat sink may be, for example, grooves which extend over the entire length or width of the peripheral edges of the base plate. Consequently, in this embodiment, at least the underside of the base plate of the heat sink is completely embedded and the peripheral edges of the base plate are at least partially embedded in the encapsulating-covering element, so that there is advantageously provided a large contact area region between the heat sink and the encapsulating-covering element. The homogeneous transition of the large contact area region provides optimum heat transmission or heat dissipation.

The heat sink in this configuration may be produced in one piece from metal, such as aluminum, copper or the like, for example, and consequently has an optimum thermal conductivity. A multiplicity of cooling ribs, formed as planar plates, may be formed on the upper side of the base plate, and run substantially parallel to one another with a distance between them. The heat sink may be arranged in such a way that the cooling ribs extend in the longitudinal direction of the printed circuit board.

In a further configuration, the heat sink is arranged directly on the sides, which are facing away from the printed circuit board, of the memory chips. In one particular configuration, the planar underside of the base plate of the heat sink is arranged directly on the sides, which are facing away from the printed circuit board, of the chips.

This means that the heat sink is incorporated in the encapsulating-covering element in such a way that the heat sink is directly in contact, at least in certain portions, with the back side of the chips (the inactive side of the chip), while other portions of the heat sink protrude beyond the upper side formed by the encapsulating-covering element. In an exemplary embodiment of the invention, the chips are unpackaged, so that the heat emission from the chip can take place directly at the heat sink. It is also possible to use packaged chips.

In a further configuration, the one or more heat sinks extend substantially over the entire length and width of the encapsulating-covering element. In this way, a single large heat transmission area is provided on the encapsulating-covering element for emitting or transmitting the heat generated by the chips to the heat sink. The generated heat is emitted or transmitted to the large base plate and then from the base plate to the multiplicity of cooling ribs, after which a further heat exchange takes place between the heat sink and the ambient air, which can be assisted by using a fan, for example.

As an alternative to this, it is also possible for a number of heat sinks to be arranged next to one another.

In another embodiment of the invention, the heat dissipating element is a cooling coil carrying a cooling medium. The cooling coil is incorporated in the encapsulating-covering element. The cooling coil may extend back and forth in a sinuously winding manner in a plane parallel to the plane of the printed circuit board within the maximum space available in the encapsulating-covering element. The connection portions of the cooling coil necessary for the circulation of the cooling medium extend from the encapsulating-covering element and are formed in such a way that they can be coupled to corresponding connecting portions of a cooling medium device (heat exchanger). Water may be used, for example, as the cooling medium.

In another embodiment of the invention, a printed circuit board is provided with an encapsulating-covering element embedding a plurality of memory chips that are electrically connected to the printed circuit board, and at least one fastening element is provided. The fastening element is either integrally attached or incorporated with the encapsulating-covering element. The fastening element projects or protrudes from the encapsulating-covering element to fasten a heat dissipating element to a fastening portion.

In one embodiment of the invention, the one or more integrally attached fastening elements is/are formed to project from the upper side. That is to say, a fastening element projects from the side of the encapsulating-covering element facing away from the printed circuit board. For example, the fastening element formed during molding may be a peripheral collar enclosing a depression on the upper side. A heat dissipating element formed to match this depression can be fit in close contact, in particular, with the bottom of the depression.

In another configuration, the integrally attached fastening element may be formed by two clamping strips arranged opposite one another and extending in the longitudinal direction of the printed circuit board. The heat dissipating element can be clamped between the clamping strips in such a way that it is in close contact with the upper side of the encapsulating-covering element.

The integrally attached fastening elements may, however, also be formed as lugs or similar structures that project from the free upper side of the encapsulating-covering element. The heat dissipating element to be fastened to these fastening portions must then be equipped with engaging recesses that correspond to the lugs or the similar structures and by means of which the heat dissipating element can be fitted onto the lugs. The engaging recesses may be dimensioned in such a way that the heat dissipating element is held, at least in certain portions, in a clamping manner on the lugs, and consequently on the encapsulating-covering element. The lugs or the similar structures may, for example, have cross-sectional shapes that constantly taper from the upper side of the encapsulating-covering element toward its respective free ends.

In an alternative configuration, the fastening portions are separate elements that are incorporated during the molding process. The fastening portions may be produced, for example, from metal and have engaging portions on their free end portions that protrude from the encapsulating-covering element. In each case, an engaging portion can be made to engage in a latching manner with a correspondingly formed engaging portion on the outer side of the heat dissipating element or in a recess on the underside of the heat dissipating element that will be fastened.

In one configuration of these embodiments, the upper side of the encapsulating-covering element and the side of the chip that is facing away from the printed circuit board are arranged in the same plane, and the heat dissipating element can be brought into engagement with at least one fastening element while thereby establishing direct contact with the chips. Such an encapsulating-covering element is in this case produced by injection molding with exposed surface portions (exposed molding). In other words by injection molding that leaves surface portions exposed, so that the inactive sides of the chips, facing away from the printed circuit board, are exposed after molding.

In a development of the invention, the printed circuit board is loaded with chips on two sides and each side of the printed circuit board has an embodiment of the encapsulating-covering element.

In one configuration of the invention, the chips are memory chips, so that the printed circuit board provides compact, less expensive memory modules. However, the printed circuit board is also suitable for other types of microelectronic components, for example, microprocessors.

In another configuration of the invention, solder bumps electrically connect the chips to the printed circuit board.

In one configuration of the invention, the encapsulating-covering element is produced from an encapsulating material having heat conducting properties that are optimized by adding suitable fillers. That is to say, the encapsulating material may be a mixture of a base material, such as, for example, an epoxy resin, to which corresponding fillers are added in a specific quantitative ratio for improving the thermal conductivity of the epoxy resin without adversely influencing other properties, such as for example, the flow behaviour of the epoxy resin.

According to an exemplary embodiment of the invention, improved heat dissipation from a printed circuit board loaded with chips is provided while at the same time, the costs for materials and production are reduced.

In an embodiment of the invention, a memory module is provided which shows a high reliability and robustness with increasing package density and complexity as well as additional mechanical protection.

In an embodiment of the invention, a memory module is provided having a printed circuit board with a lateral contact portion, a plurality of memory chips being electrically coupled to the printed circuit board. The memory chips are arranged next to one another on at least one printed circuit board assembly side, wherein an encapsulating-covering element (which may be made of resin mold material, for example) is arranged on (e.g., formed on, e.g., molded) at least one assembly side of the assembly sides of the printed circuit board. In an embodiment of the invention, the plurality of memory chips may be embedded into the encapsulating-covering element.

In an embodiment of the invention, the memory module includes a plurality of memory chips which are electrically coupled to the printed circuit board. The memory chips may be arranged (e.g., respectively side-by-side) either only on one printed circuit board assembly side of the two printed circuit board assembly sides or on both printed circuit board assembly sides.

In an embodiment of the invention, in addition to the memory chips, additional electronic components, e.g., passive electronic components such as, e.g., an ohmic resistance, a capacitor, an inductor or the like, may be arranged on the printed circuit board. An encapsulating-covering element (e.g., made of a resin mold material) is formed on the printed circuit board, in which the plurality of memory chips and the possible additional electronic components (active components or passive components) may be embedded.

In an embodiment of the invention, the encapsulating-covering element has a plane upper surface. The lateral edge portions of the encapsulating-covering element are formed in an inclined manner starting from the upper side of the printed circuit board to the upper side of the encapsulating-covering element. The encapsulating-covering element may be manufactured using an injection-molding process, for example, wherein a composite structure is formed between the printed circuit board and the encapsulating-covering element.

The resin mold material for the encapsulating-covering element may include an epoxy resin, for example. Filling material may be added to the epoxy resin, wherein the filling material may be selected such that it improves the heat dissipation behaviour of the resin mold material.

The memory chips of the memory module may be packaged chips or unpackaged chips. In an embodiment of the invention, the memory chips may be wafer level package (WLP) chips.

The memory module having the encapsulating-covering element formed thereon shows a compact design, is robust, protects all of the memory chips and possible additional electronic components arranged on the printed circuit board against dust from the environment.

In case that unpackaged WLP chips are used for manufacturing the memory module, a memory module having an improved package density may be provided. The protection of the memory chips is ensured by the encapsulating-covering element, in which the memory chips are embedded. Since mold material may also be present in (and thus may fill) the spacing between the side of the memory chips facing the printed circuit board and the printed circuit board (e.g., by embedding the connecting elements to electrically connect the memory chips with terminals of the printed circuit board in mold material), it is not necessary to provide an expensive underfiller under the memory chips.

In an embodiment of the invention, the memory module has the effect that independent from the design (e.g., characterized by the height or the thickness of the memory chips) and the constitution (e.g., packaged or unpackaged) of the memory chips on the printed circuit board, a smooth surface of the memory module may be provided by means of the encapsulating-covering element. In an embodiment of the invention, the memory module may have a dimension such that it corresponds to a standardized memory module.

In an embodiment of the invention, a memory module is provided having a printed circuit board including a lateral contact portion. Furthermore, a plurality of memory chips are electrically coupled to the printed circuit board and are arranged side-by-side at least one printed circuit board assembly side. Moreover, an encapsulating-covering element is formed on the printed circuit board at the at least one printed circuit board assembly side, e.g., by means of molding, e.g., injection molding. At least one heat dissipating element is integrally attached to the encapsulating-covering element or incorporated with the encapsulating-covering element. The plurality of memory chips may be embedded in the encapsulating-covering element.

What is claimed is:

1. A memory module, comprising:
a printed circuit board having a lateral contact portion;
a plurality of memory chips electrically coupled to the printed circuit board and arranged side-by-side at least one printed circuit board assembly side; and
an encapsulating-covering element formed on the printed circuit board at the at least one printed circuit board assembly side, wherein the plurality of memory chips are embedded in the encapsulating-covering element.

2. The memory module according to claim 1, wherein the encapsulating-covering element is made of resin.

3. The memory module according to claim 1, wherein the memory chips are packaged memory chips.

4. The memory module according to claim 1, wherein the memory chips are unpackaged memory chips.

5. The memory module according to claim 1, wherein the memory chips are wafer level packaged memory chips.

6. The memory module according to claim 1, further comprising at least one heat dissipating element integrally attached to the encapsulating-covering element or incorporated with the encapsulating-covering element.

7. The memory module according to claim 6, wherein the heat dissipating element comprises a cooling rib produced in one piece with the encapsulation-covering element.

8. The memory module according to claim 7, wherein:
the encapsulating-covering element includes an upper side;
the printed circuit board extends in a longitudinal direction; and
the cooling rib projects from the upper side of the encapsulating-covering element and extends in a direction selected from a group consisting of a direction along the longitudinal direction of the printed circuit board, a direction transverse to the longitudinal direction, and a direction oblique to the longitudinal direction.

9. The memory module according to claim 6, wherein:
the heat dissipating element includes a plurality of cooling ribs produced in one piece with the encapsulation-covering element; and
the plurality of cooling ribs is configured at a distance from one another.

10. The memory module according to claim 7, wherein:
the printed circuit board extends in a plane;
the encapsulating-covering element includes at least one peripheral edge formed with at least one depression extending substantially parallel to the plane of the printed circuit board; and
the depression defines a cooling rib produced in one piece with the encapsulation-covering element.

11. The memory module according to claim 6, wherein:
the encapsulating-covering element includes an upper side;
the heat dissipating element includes a heat sink configured on the upper side of the encapsulating-covering element; and
the heat sink includes a plurality of portions incorporated in the encapsulating-covering element.

12. The memory module according to claim 11, wherein:
the heat sink includes a base plate with an upper side including a plurality of cooling ribs; and
the heat sink is formed with two peripheral edge recesses filled with a casting compound.

13. The memory module according to claim 11, wherein:
the plurality of memory chips includes a plurality of sides facing away from the printed circuit board; and
the heat sink is arranged directly on the plurality of the sides, which are facing away from the printed circuit board, of the plurality of memory chips.

14. The memory module according to claim 11, wherein:
the encapsulating-covering element includes a length; and
the heat sink extends substantially entirely over the length of the encapsulating-covering element.

15. The memory module according to claim 11, further comprising a plurality of heat sinks arranged side-by-side.

16. The memory module according to claim 6, wherein:
the encapsulating-covering element includes an upper side;
the heat dissipating element includes a plurality of heat sinks configured next to each other on the upper side of the encapsulating-covering element; and
each one of the plurality of heat sinks includes a plurality of portions incorporated in the encapsulating-covering element.

17. The memory module according to claim 6, wherein:
the heat dissipating element includes a cooling coil for carrying a cooling medium; and
the heat dissipating element is incorporated in the encapsulating-covering element.

18. The memory module according to claim 1, wherein:
the encapsulating-covering element includes at least one protruding fastening element fastening the heat dissipating element; and
the fastening element is integrally attached to the encapsulating-covering element or incorporated with the encapsulating-covering element.

19. The memory module according to claim 18, wherein:
the encapsulating-covering element includes an upper side defining a plane;
the plurality of memory chips includes a plurality of sides facing away from the printed circuit board and configured in the plane defined by the upper side of the encapsulating-covering element; and
the heat dissipating element is connected with a form fit to the fastening element and directly contacts the plurality of memory chips.

20. The memory module according to claim 1, further comprising a plurality of solder bumps electrically connecting the plurality of memory chips to the printed circuit board.

21. The memory module according to claim 1, wherein:
the encapsulation-covering element is formed from an encapsulating material exhibiting heat conducting properties; and
the encapsulating material includes fillers affecting heat conducting properties.

22. The memory module according to claim 1, wherein the encapsulating-covering element comprises an injection-molded component.

23. The memory module according to claim 1, further comprising:
a second encapsulating-covering element;
at least one heat dissipating element integrally attached to the second encapsulating-covering element or incorporated with the second encapsulating-covering element; and
a second plurality of memory chips, wherein:
the printed circuit board includes a first side and a second side;
the plurality of memory chips are configured on the first side of the printed circuit board and the second plurality of chips are configured on the second side of the printed circuit board;
the encapsulating-covering element embeds the first plurality of memory chips; and
the second encapsulating-covering element embeds the second plurality of memory chips.

24. A memory module, comprising:
a printed circuit board;
an encapsulating-covering element;
a plurality of memory chips embedded in the encapsulating-covering element and electrically connected to the printed circuit board; and
at least one heat dissipating element integrally attached to the encapsulating-covering element or incorporated with the encapsulating-covering element.

25. The memory module according to claim 24, wherein the heat dissipating element is a cooling rib produced in one piece with the encapsulation-covering element.

26. The memory module according to claim 25, wherein:
the encapsulating-covering element includes an upper side;
the printed circuit board extends in a longitudinal direction; and
the cooling rib projects from the upper side of the encapsulating-covering element and extends in a direction selected from a group consisting of a direction along the longitudinal direction of the printed circuit board, a direction transverse to the longitudinal direction, and a direction oblique to the longitudinal direction.

27. The memory module according to claim 24, wherein:
the heat dissipating element includes a plurality of cooling ribs produced in one piece with the encapsulation-covering element; and
the plurality of cooling ribs are configured at a distance from one another.

28. The memory module according to claim 24, wherein:
the printed circuit board extends in a plane; and
the encapsulating-covering element includes at least one peripheral edge formed with at least one depression extending substantially parallel to the plane of the printed circuit board; and
the depression defines a cooling rib produced in one piece with the encapsulation-covering element.

29. The memory module according to claim 24, wherein:
the encapsulating-covering element includes an upper side;
the heat dissipating element includes a heat sink configured on the upper side of the encapsulating-covering element; and
the heat sink includes a plurality of portions incorporated in the encapsulating-covering element.

30. The memory module according to claim 29, wherein:
the heat sink includes a base plate with an upper side including a plurality of cooling ribs; and
the heat sink is formed with two peripheral edge recesses filled with a casting compound.

31. The memory module according to claim 29, wherein:
the plurality of memory chips includes a plurality of sides facing away from the printed circuit board; and
the heat sink is arranged directly on the plurality of the sides, which are facing away from the printed circuit board, of the plurality of memory chips.

32. The memory module according to claim 29, wherein:
the encapsulating-covering element includes a length; and
the heat sink extends substantially entirely over the length of the encapsulating-covering element.

33. The memory module according to claim 24, wherein:
the encapsulating-covering element includes an upper side;
the heat dissipating element includes a plurality of heat sinks configured next to each other on the upper side of the encapsulating-covering element; and
each one of the plurality of heat sinks includes a plurality of portions incorporated in the encapsulating-covering element.

34. The memory module according to claim 24, wherein:
the heat dissipating element includes a cooling coil for carrying a cooling medium; and
the heat dissipating element is incorporated in the encapsulating-covering element.

35. The memory module according to claim 24, further comprising a plurality of solder bumps electrically connecting the plurality of memory chips to the printed circuit board.

36. The memory module according to claim 24, wherein:
the encapsulation-covering element is formed from an encapsulating material exhibiting heat conducting properties; and
the encapsulating material includes fillers affecting the heat conducting properties.

37. The memory module according to claim 24, wherein the encapsulating-covering element comprises an injection-molded component.

38. The memory module according to claim 24, further comprising:
a first encapsulating-covering element defined by the encapsulating-covering element;
a second encapsulating-covering element;
at least one heat dissipating element integrally attached to the second encapsulating-covering element or incorporated with the second encapsulating-covering element;
a first plurality of memory chips defined by the plurality of memory chips; and
a second plurality of memory chips;
the printed circuit board including a first side and a second side;
the first plurality of memory chips configured on the first side of the printed circuit board and the second plurality of memory chips configured on the second side of the printed circuit board;
the first encapsulating-covering element embedding the first plurality of memory chips; and
the second encapsulating-covering element embedding the second plurality of memory chips.

39. A memory module, comprising:
a printed circuit board;
an encapsulating-covering element;
a plurality of memory chips embedded in the encapsulating-covering element and electrically connected to the printed circuit board;
a heat dissipating element;
the encapsulating-covering element including at least one protruding fastening element fastening the heat dissipating element; and
the fastening element integrally attached to the encapsulating-covering element or incorporated with the encapsulating-covering element.

40. The memory module according to claim 39, wherein:
the encapsulating-covering element includes an upper side defining a plane;
the plurality of chips includes a plurality of sides facing away from the printed circuit board and configured in the plane defined by the upper side of the encapsulating-covering element; and
the heat dissipating element is connected with a form fit to the fastening element and directly contacts the plurality of memory chips.

41. The memory module according to claim 39, further comprising a plurality of solder bumps electrically connecting the plurality of memory chips to the printed circuit board.

42. The memory module according to claim 39, wherein:
the encapsulation-covering element is formed from an encapsulating material exhibiting heat conducting properties; and
the encapsulating material includes fillers affecting the heat conducting properties.

43. The memory module according to claim 39, wherein the encapsulating-covering element comprises an injection-molded component.

44. The memory module according to claim 39, further comprising:
a first encapsulating-covering element defined by the encapsulating-covering element;
a second encapsulating-covering element;
at least one heat dissipating element integrally attached to the second encapsulating-covering element or incorporated with the second encapsulating-covering element;
a first plurality of memory chips defined by the plurality of memory chips;
a second plurality of memory chips;
the printed circuit board including a first side and a second side;
the first plurality of memory chips being configured on the first side of the printed circuit board and the second plurality of memory chips being configured on the second side of the printed circuit board;
the first encapsulating-covering element embedding the first plurality of memory chips; and
the second encapsulating-covering element embedding the second plurality of memory chips.

45. A memory module, comprising:
a printed circuit board having a lateral contact portion;
a plurality of memory chips electrically coupled to the printed circuit board and arranged
side-by-side at least one printed circuit board assembly side;
an encapsulating-covering element formed on the printed circuit board at the at least one
printed circuit board assembly side, wherein the plurality of memory chips are embedded in the encapsulating-covering element; and
at least one heat dissipating element integrally attached to the encapsulating-covering element or incorporated with the encapsulating-covering element.
